(19) United States
(12) Patent Application Publication
(10) Pub. No.: US 2025/0038125 A1
(43) Pub. Date: Jan. 30, 2025

(54) APPARATUS AND METHOD FOR FORMING EMI SHIELDING FILM

(71) Applicant: SAMSUNG ELECTRONICS CO., LTD., Suwon-si (KR)

(72) Inventors: Sanghyeon JEONG, Suwon-si (KR); Youngmin LEE, Suwon-si (KR)

(73) Assignee: SAMSUNG ELECTRONICS CO., LTD., Suwon-si (KR)

(21) Appl. No.: 18/623,309

(22) Filed: Apr. 1, 2024

(30) Foreign Application Priority Data
Jul. 28, 2023 (KR) 10-2023-0098988
Oct. 20, 2023 (KR) 10-2023-0141294

(51) Int. Cl. H01L 23/552; H01L 21/56

(52) U.S. Cl. CPC H01L 23/552; H01L 21/56

(57) ABSTRACT

An apparatus for forming an electromagnetic interference (EMI) shielding film, includes an adhesive member having a pocket region, a support member disposed on or below the adhesive member, the support member having an opening at a position aligned with the pocket region, a coating member configured to form a shielding material layer on the adhesive member and the chip structure disposed on the adhesive member, and a pickup member configured to detach, from the adhesive member, the chip structure covered by the shielding material layer. The support member has a first side surface defining a lower region of the opening, and a second side surface spaced apart from the first side surface in a first direction, the second surface defining an upper region of the opening. A width of the lower region in the first direction is less than a width of the upper region in the first direction.

### CROSS-REFERENCE TO RELATED APPLICATION(S)

This application claims benefit of priority to Korean Patent Application Nos. 10-2023-0098988, filed on Jul. 28, 2023, and 10-2023-0141294, filed on Oct. 20, 2023, in the Korean Intellectual Property Office, the disclosures of which are herein incorporated by reference in their entireties.

### BACKGROUND

The inventive concept relates to an apparatus and a method for forming an electromagnetic interference (EMI) shielding film, more specifically, to an apparatus and a method for forming an EMI shielding film for a semiconductor package.

In order to protect users of electronic devices or semiconductor chips from electromagnetic interference (EMI), EMI shielding of semiconductor packages is required. Accordingly, research and development of a technology for forming EMI shielding films suitable for various types of semiconductor packages have been conducted.

### SUMMARY

An aspect of the inventive concept provides an apparatus and a method for forming an electromagnetic interference (EMI) shielding film having improved yield.

According to an aspect of the inventive concept, there is provided an apparatus for forming an EMI shielding film, the apparatus including an adhesive member having a pocket region in which bumps of a chip structure are accommodated, a support member disposed on or below the adhesive member, the support member having an opening at a position aligned with the pocket region, a coating member configured to form a shielding material layer on the adhesive member and the chip structure disposed on the adhesive member, and a pickup member configured to detach, from the adhesive member, the chip structure covered by the shielding material layer. The support member may have a first side surface defining a lower region of the opening, and a second side surface spaced apart from the first side surface in a first direction, the second surface defining an upper region of the opening. A first width of the lower region in the first direction may be less than a second width of the upper region in the first direction.

According to another aspect of the inventive concept, there is provided an apparatus for forming an EMI shielding film, the apparatus including an adhesive member having a pocket region in which bumps of a chip structure are accommodated, a support member disposed on or below the adhesive member, the support member having an opening at a position aligned with the pocket region, a coating member configured to form a shielding material layer on the adhesive member and the chip structure disposed on the adhesive member, and a pickup member configured to detach, from the adhesive member, the chip structure covered by the shielding material layer. The support member may have a first side surface defining a lower region of the opening, a second side surface defining an upper region of the opening, and a third side surface in contact with the adhesive member, the third side surface being inclined at an angle with respect to the second side surface.

According to another aspect of the inventive concept, there is provided a method for forming an EMI shielding film, the method including attaching an adhesive member to a support member having a plurality of openings, forming, in the adhesive member, a plurality of pocket regions at positions respectively aligned with the plurality of openings, attaching, to the adhesive member, chip structures respectively corresponding to the plurality of pocket regions, forming a shielding material layer having first portions respectively covering side surfaces of the chip structures, and second portions extending from the first portions, the second portions covering the adhesive member, adsorbing, by a pickup member at a first level, at least one chip structure, among the chip structures covered by the shielding material layer, lowering the pickup member to a second level, which is lower than the first level, such that an angle between a first portion and a second portion of the shielding material layer decreases, and raising the pickup member to a third level, which is higher than the first level, such that the first portion of the shielding material layer is separated from the second portion.

### BRIEF DESCRIPTION OF DRAWINGS

The above and other aspects, features, and advantages of example embodiments of the inventive concept will be more clearly understood from the following detailed description, taken in conjunction with the accompanying drawings, in which:

FIG. 1 is a flowchart illustrating an electromagnetic interference (EMI) shielding film forming method according to an example embodiment;

FIGS. 2A to 2F are cross-sectional views illustrating an EMI shielding film forming method according to an example embodiment;

FIG. 3A is a plan view of a support member applicable to an EMI shielding film forming apparatus according to an example embodiment, and FIG. 3B is a cross-sectional view taken along line I-I′ of FIG. 3A;

FIGS. 4A to 4C are diagrams illustrating support members according to example embodiments; and

FIGS. 5A to 5D are cross-sectional views illustrating an EMI shielding film forming method according to an example embodiment.

### DETAILED DESCRIPTION

Hereinafter, example embodiments will be described in detail. Unless otherwise described, the terms such as “upper,” “upper portion,” “upper surface,” “lower,” “lower portion,” “lower surface,” and “side surface” are based on the drawings, and may vary depending on a direction in which an element or component is actually arranged.

In addition, ordinal numbers such as “first,” “second,” “third,” and the like may be used as labels for specific elements, operations, directions, and the like, to distinguish various elements, steps, directions, and the like from one another. A term, not described in the specification using “first,” “second,” and the like, may still be referred to as “first” or “second” in the claims. In addition, a term referenced by a particular ordinal number (for example, “first” in a particular claim) may be described elsewhere with a different ordinal number (for example, “second” in the specification or another claim).

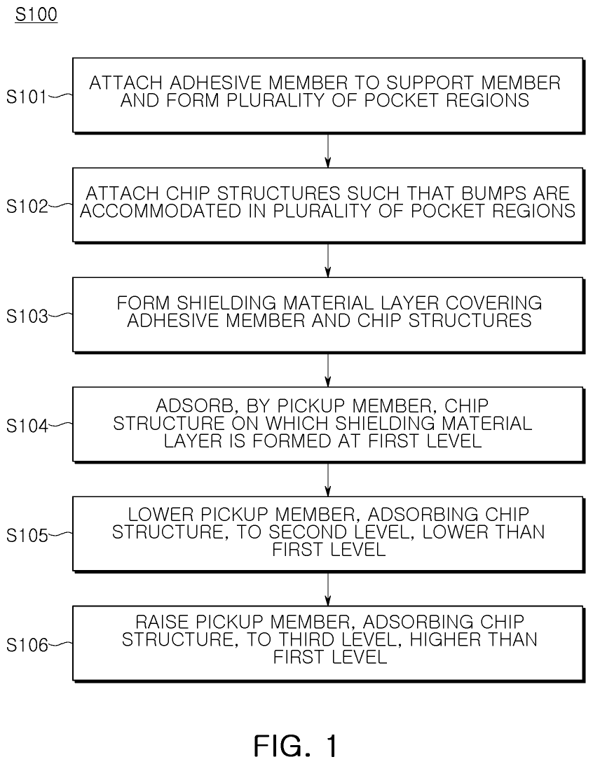

FIG. 1 is a flowchart illustrating an electromagnetic interference (EMI) shielding film forming method (S100) according to an example embodiment.

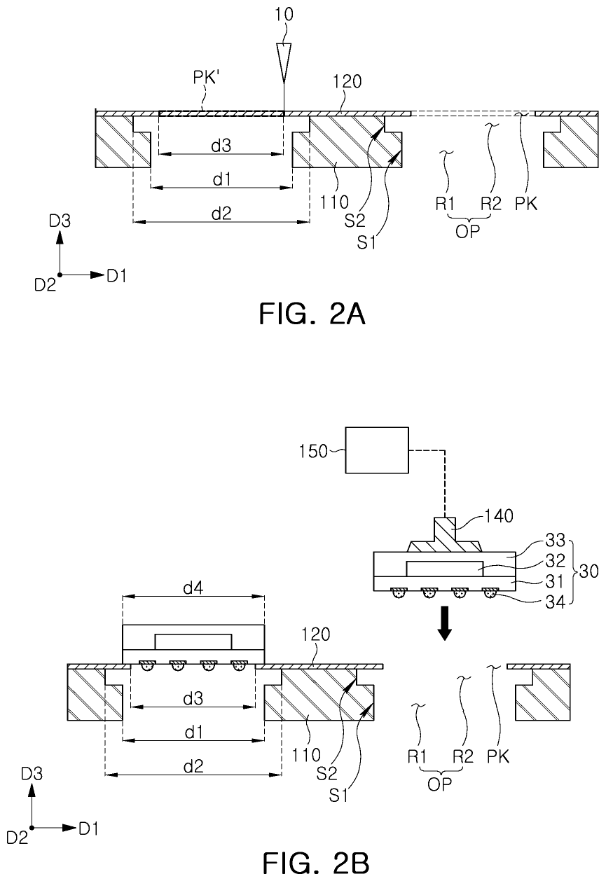

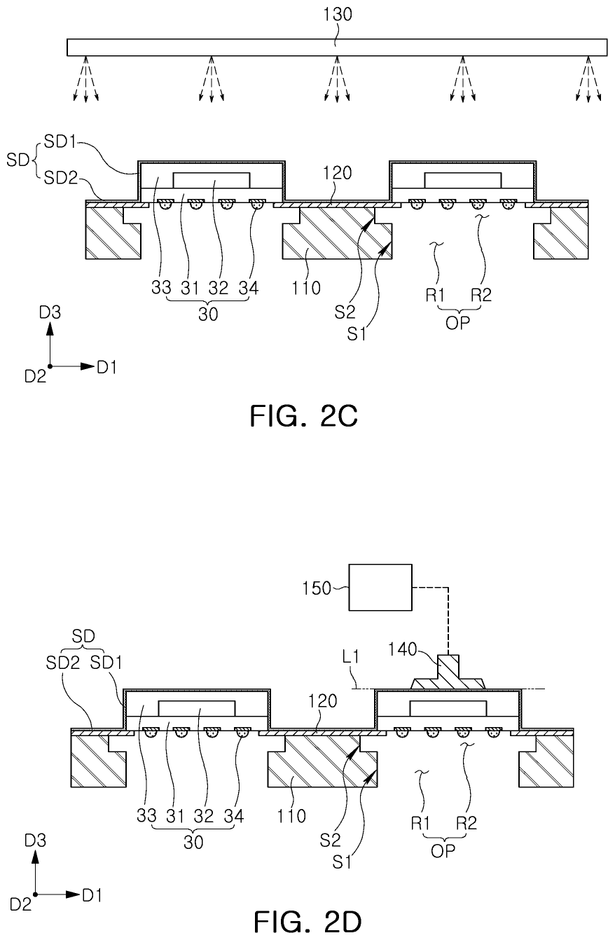

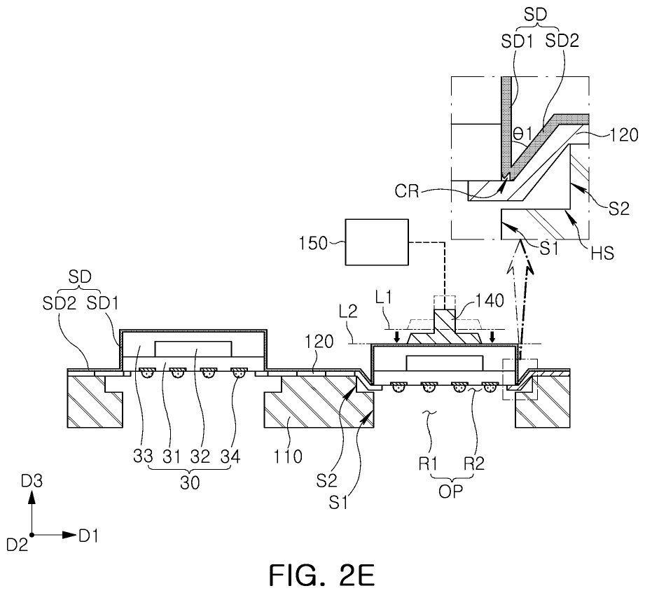

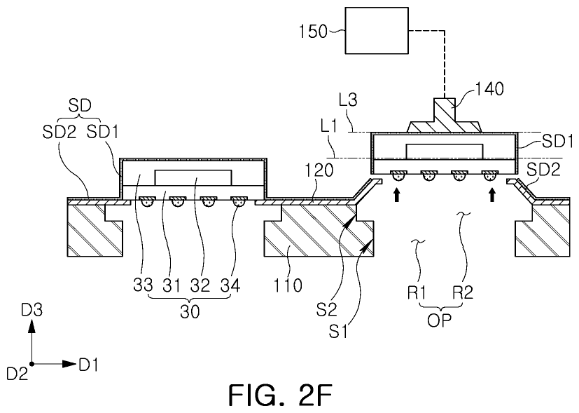

Referring to FIG. 1, the EMI shielding film forming method (S100) according to an example embodiment may be an EMI shielding method for a chip structure (e.g., “30” in FIG. 2B). Hereinafter, the EMI shielding film forming method (S100) may be referred to as an EMI shielding method for brevity of description. The “chip structure” may include a semiconductor chip with bumps or a semiconductor package (for example, a ball grid array (BGA)-type package) with bumps.

The EMI shielding film forming method (S100) according to an example embodiment may include attaching an adhesive member to a support member and forming a plurality of pocket regions (S101), attaching chip structures such that bumps are accommodated in the plurality of pocket regions (S102), forming a shielding material layer covering the adhesive member and the chip structures (S103), adsorbing, by a pickup member, a chip structure on which the shielding material layer is formed at a first level (S104), lowering the pickup member, adsorbing the chip structure, to a second level, lower than the first level (S105), and raising the pickup member, adsorbing the chip structure, to a third level, higher than the first level (S106).

The EMI shield forming method (S100) according to an example embodiment may include sequentially moving the pickup member to a first level, to a second level, lower than the first level, and to a third level, higher than the first level. In the related art, when the pickup member, adsorbing the chip structure on which the shielding material layer is formed, is raised to detach the chip structure, a burr may occur at a cut portion of the shielding material layer, resulting in a short circuit and poor exterior. The EMI shield forming method (S100) according to an example embodiment may prevent the occurrence of such a burr and thereby improve yield. When the pickup member is moved to the second level, the shielding material layer between the chip structure and the adhesive member may bend outwardly, which may cause a crack to occur on the inside of the shielding material layer to which tensile stress is applied. When the pickup member is moved to the third level, the shielding material layer in which a crack occurs may be entirely cut, thereby separating the EMI shielding film covering the chip structure from the shielding material layer.

Hereinafter, the EMI shielding film forming method (S100) according to an example embodiment will be described in detail with reference to FIGS. 2A to 2F.

FIGS. 2A to 2F are cross-sectional views illustrating an EMI shielding film forming method (S100) according to an example embodiment.

Referring to FIGS. 1 and 2A, an adhesive member 120 may be attached to a support member 110 having a plurality of openings OP, and a plurality of pocket regions PK, at positions respectively aligned with the plurality of openings OP, may be formed in the adhesive member 120 (S101).

The support member 110 may be formed of a material having rigidity to support the adhesive member 120 to which a chip structure (e.g., “30” in FIG. 2B) is attached, and processability to be processed into the form of an opening OP to be described below. For example, the support member 110 may be a stencil formed of metal. An adhesive material layer for temporarily fixing the adhesive member 120 may be disposed on an upper surface of the support member 110, but the inventive concept is not limited thereto.

Each of the plurality of openings OP may have a lower region R1 and an upper region R2 on the lower region R1. A width d1 of the lower region R1 may be less than a width d2 of the upper region R2, but the inventive concept is not limited thereto. In some example embodiments, the width d1 of the lower region R1 may be equal to or greater than the width d2 of the upper region R2.

The adhesive member 120 may be an adhesive film having at least one side surface coated with adhesive. The adhesive may be a pressure sensitive adhesive (PSA), but the inventive concept is not limited thereto. For example, the adhesive member 120 may be a double-sided tape in which adhesive is applied to both surfaces of a polyimide film.

The plurality of pocket regions PK may be formed by removing a portion PK′ of the adhesive member 120 using a cutting device 10. For example, the cutting device 10 may be a laser cutting device, but the inventive concept is not limited thereto. The plurality of pocket regions PK may be formed to have a width less than the width d2 of the upper region R2 of each of the plurality of openings OP. A width d3 of each of the plurality of pocket regions PK may be less than the width d2 of the upper region R2 of each of the openings OP. Such a configuration may be to secure a space for lowering of the chip structure, which will be described in more detail with reference to FIG. 2E. In the drawings, it is illustrated that the width d3 of each of the plurality of pocket regions PK is less than the width d1 of the lower region R1 of each of the openings OP, but the inventive concept is not limited thereto. In some example embodiments, the width d3 of each of the plurality of pocket regions PK may be equal to or greater than the width d1 of the lower region R1 of the openings OP.

Referring to FIGS. 1 and 2B, chip structures 30 respectively corresponding to the plurality of pocket regions PK may be attached to the adhesive member 120 (S102).

The chip structures 30 may be in contact with the adhesive member 120 in a peripheral region in which bumps 34 are not disposed. For example, the peripheral region may be a region between an outermost bump 34 and an edge of the substrate 31. The peripheral region may be about 100 μm or more, but the inventive concept is not limited thereto. Accordingly, a width d4 of each of the chip structures 30 in a first direction D1 may be greater than the width d3 of each of the plurality of pocket regions PK in the first direction D1.

In addition, the width d4 of each of the chip structures 30 may be smaller than the width d2 of the upper region R2 of each of the openings OP. Accordingly, a space in which the chip structure 30 is lowered may be provided during a process of detaching the chip structure 30 to be described below (see e.g., FIG. 2E).

The chip structure 30 may be a semiconductor package including a substrate 31, a semiconductor chip 32, a mold 33, and bumps 34. The substrate 31 may be a package substrate (for example, printed circuit board) on which the semiconductor chip 32 is mounted. The semiconductor chip 32 may be electrically connected to the substrate 31 in a flip chip manner or a wire bonding manner. The number of the semiconductor chips 32 may be greater than the number of those illustrated in the drawings. For example, the chip structure 30 may include a plurality of semiconductor chips vertically and/or horizontally disposed on the substrate 31.

The semiconductor chip 32 include a logic chip including a central processor (CPU), a graphics processor (GPU), a field programmable gate array (FPGA), a digital signal processor (DSP), an encryption processor, a microprocessor, microcontrollers, an analog-to-digital converter, or an application-specific IC (ASIC) and/or a memory chip including a volatile memory such as, for example, a dynamic RAM (DRAM) or a static RAM (SRAM), and a non-volatile memory such as, for example, a phase change RAM (PRAM), a magnetic RAM (MRAM), a resistive RAM (RRAM), or flash memory.

The mold 33 may be formed of an insulating resin for sealing the semiconductor chip 32, for example, a thermosetting resin such as an epoxy resin, a thermoplastic resin such as polyimide, or a prepreg, an Ajinomoto build-up film (ABF), FR-4, bismaleimide-triazine (BT), or an epoxy molding compound (EMC).

The bumps 34 may be arranged on a lower surface of the substrate 31. The semiconductor chip 32 may be connected to an external device such as a module substrate or main board via the bumps 34. The bumps 34 may include a low melting point metal, for example, tin (Sn) or an alloy including tin (Sn) (for example, Sn—Ag—Cu, Sn—Ag, or the like). In some example embodiments, the bumps 34 may be in the form of a combination of a pillar and a ball. The bumps 34 may be disposed within the pocket region PK of the adhesive member 120, and thus an EMI shielding method according to an example embodiment may be applied to various forms of chip structures 30 without being limited by a size (for example, height) of each of the bumps 34. For example, the height of each of the bumps 34 may be about 150 μm or more, but the inventive concept is not limited thereto.

The chip structures 30 may be aligned on the plurality of pocket regions PK and the plurality of openings OP by a pickup member 140. The pickup member 140 may be operated to attach and detach the chip structure 30 to and from the adhesive member 120. The pickup member 140 may be a pick-and-place device configured to vacuum-suction the chip structure 30.

A control member 150 may include one or more memories and one or more processors to control an operation of the pickup member 140. The one or more memories and processors may be implemented as hardware, firmware, software, or any combination(s) thereof. For example, the one or more processors may include a computing device such as a workstation computer, a desktop computer, a laptop computer, a tablet computer, or the like. The one or more memories and processors may be implemented, for example, by a general-purpose computer or application-specific hardware such as a digital signal processor (DSP), a field programmable gate array (FPGA), and an application specific integrated circuit (ASIC).

Referring to FIGS. 1 and 2C, a shielding material layer SD, covering the chip structures 30 and the adhesive member 120, may be formed using a coating member 130 (S103).

The coating member 130 may form the shielding material layer SD by performing a deposition process such as physical vapor deposition (PVD) or chemical vapor deposition (CVD). For example, the coating member 130 may be a sputtering device, but the inventive concept is not limited thereto.

The shielding material layer SD may be a thin film formed along a surface of each of the chip structures 30 and the adhesive member 120. A thickness of the shielding material layer SD may be about 5 μm or less, but the inventive concept is not limited thereto. The shielding material layer SD may include a conductive material for shielding of EMI, for example, iron (Fe), nickel (Ni), gold (Au), silver (Ag), copper (Cu), and an alloy thereof. The shielding material layer SD may include at least one-layer conductive thin film. For example, the shielding material layer SD may be a three-layer thin film obtained by sequentially stacking a stainless steel (SUS) film, a copper (Cu) film, and a stainless steel (SUS) film.

The shielding material layer SD may have first portions SD1 respectively covering upper surfaces and side surfaces of the chip structures 30, and second portions SD2 extending from the first portions SD1, the second portions SD2 covering an upper surface of the adhesive member 120 exposed from the chip structures 30. The shielding material layer SD may be bent between the first portions SD1 and the second portions SD2. For example, an end of the first portion SD1 may be bent and extend into the second portion SD2.

Referring to FIGS. 1 and 2D, the pickup member 140 may adsorb at least one chip structure 30, among the chip structures 30 covered by the shielding material layer SD, at a first level L1 (S104). For example, the first level L1 may correspond to a height of the first portion SD1 of the shielding material layer SD from the adhesive member 120, but the inventive concept is not limited thereto. The pickup member 140 may adsorb the first portion SD1 of the shielding material layer SD1. Thereafter, the pickup member 140 may be lowered to a level, lower than the first level L1, by the control member 150 to move the adsorbed chip structure 30 into the opening OP.

Referring to FIGS. 1 and 2E, the pickup member 140 may be lowered to a second level L2 (S105). When the pickup member 140 is lowered to the second level L2, a portion of a corresponding chip structure 30 may be positioned within the upper region R2 of the opening OP. As described above, the upper region R2 of the opening OP may have a width and planar area greater than those of the chip structure 30, thereby providing a space for lowering of the chip structure 30.

As the pickup member 140 is lowered, the shielding material layer SD between the first portion SD1 and the second portion SD2 may be bent, and an angle between the first portion SD1 and the second portion SD2 may decrease. For example, at the second level L2, the first portion SD1 and the second portion SD2 may have a first angle θ1 therebetween. When the pickup member 140 is lowered to the second level L2, a crack CR may occur between the first portion SD1 and the second portion SD2 of the shielding material layer SD to which tensile stress is applied.

Thus, for detachment of the chip structure 30, the control member 150 according to an example embodiment may control an operation of the pickup member 140, such that a crack CR may occur between the first portion SD1 and the second portion SD2 of the shielding material layer SD. According to the EMI shielding method according to an example embodiment, the pickup member 140, adsorbing the chip structure 30, may be lowered to the second level L2, thereby facilitating cutting of the shielding material layer SD and preventing the occurrence of a burr. The second level L2 may be preset in consideration of a thickness of the shielding material layer SD, a tensile strength of the shielding material layer SD, and the like. A height of the pickup member 140 may be controlled by the control member 150, and thus may stop at the second level L2 without being in contact with the support member 110.

In some example embodiments, as the chip structure 30 is lowered, a lowermost end of the adhesive member 120 may be in contact with the support member 110. For example, at the second level L2, a portion of the adhesive member 120, attached to a lower portion of the chip structure 30, may be in contact with a horizontal surface HS of the support member 110 between a first side surface S1 and a second side surface S2 of the support member 110, thereby preventing the adhesive member 120 from being bent and separated from the chip structure 30.

Referring to FIGS. 1 and 2F, the pickup member 140 may be raised to a third level L3, higher than the first level L1 (S106). When the pickup member 140 is raised to the third level L3, the first portion SD1 of the shielding material layer SD and the second portion SD2 of the shielding material layer SD may be separated from each other. The first portion SD1 of the shielding material layer SD may function as an EMI shielding film for the chip structure 30. Here, the third level L3 may not indicate a pre-defined value but is used to describe a concept that the pickup member 140 is raised to a level such that the first portion SD1 and the second portion SD2 are entirely separated from each other, and it does not mean that the pickup member 140 is raised only to the third level L3.

Referring to FIGS. 2A to 2F together, the EMI shielding film forming method (S100) according to the above-described example embodiment may be implemented by the following EMI shielding film forming apparatus according to an example embodiment.

The EMI shielding film forming apparatus according to an example embodiment may include the support member 110 having a space (e.g., upper region R2) in which the chip structure 30 is lowered. For example, the EMI shielding film forming apparatus according to an example embodiment may include the adhesive member 120 having the pocket region PK in which the bumps 34 of the chip structure 30 are accommodated, the support member 110 disposed on or below the adhesive member 120, the support member 110 having the opening OP aligned with the pocket region PK, the coating member 130 configured to form the shielding material layer SD on the adhesive member 120 and the chip structure 30 disposed on the adhesive member 120, and the pickup member 140 configured to detach, from the adhesive member 120, the chip structure 30 covered by the shielding material layer SD. The support member 110 according to an example embodiment may have the first side surface S1 defining the lower region R1 of the opening OP, and the second side surface S2 spaced apart from the first side surface S1 in the first direction D1, the second side surface S2 defining the upper region R2 of the opening OP. Here, the width d1 of the lower region R1 in the first direction D1 may be less than the width d2 of the upper region R2 in the first direction D1.

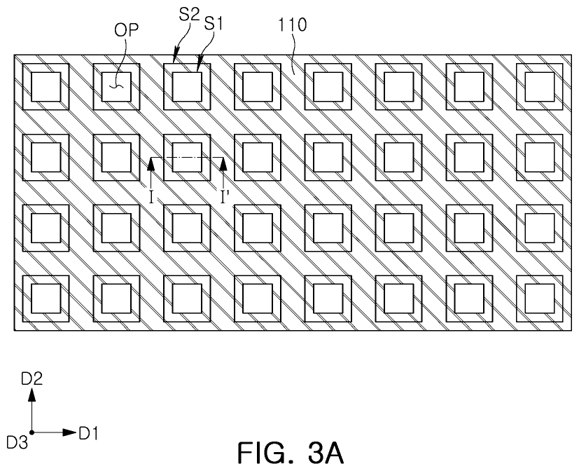

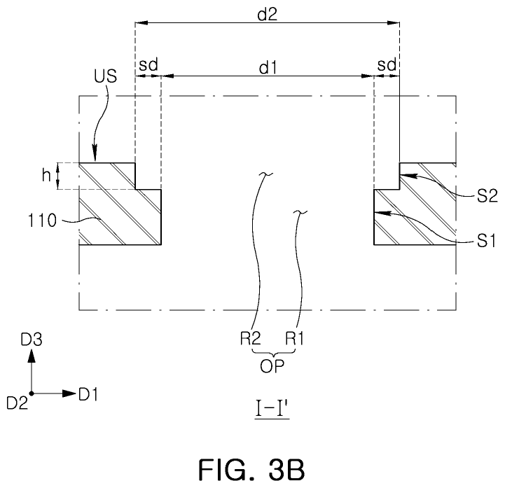

Hereinafter, the support member 110 according to an example embodiment will be further described with reference to FIGS. 3A and 3B.

FIG. 3A is a plan view of a support member 110 applicable to an EMI shielding film forming apparatus according to an example embodiment, and FIG. 3B is a cross-sectional view taken along line I-I′ of FIG. 3A.

Referring to FIGS. 3A and 3B, the support member 110 according to an example embodiment may be a rectangular stencil. The support member 110 may have a plurality of openings OP arranged to be vertically and horizontally adjacent to each other. The support member 110 may have internal side surfaces S1 and S2 defining the plurality of openings OP. The internal side surfaces S1 and S2 may have a first side surface S1 defining a lower region R1 of each of the plurality of openings OP, and a second side surface S2 defining an upper region R2 of each of the plurality of openings OP. The support member 110 may have a support surface US to which an adhesive member (e.g., “120” in FIG. 2A) is attached.

In order to secure a width of the upper region R2, the second side surface S2 may be spaced apart from the first side surface S1 in a horizontal direction D1. A separation distance sd between the first side surface S1 and the second side surface S2 may be about 50 μm or more, for example, in a range of about 50 μm to about 500 μm, about 50 μm to about 400 μm, about 50 μm to about 300 μm, about 50 μm to about 200 μm, about 50 μm to about 100 μm, or the like, but the inventive concept is not limited thereto. The separation distance sd between the first side surface S1 and the second side surface S2 may be determined in consideration of a width d1 of the lower region R1 and a width of the chip structure (e.g., “30” in FIG. 2B).

In order to secure a depth of the upper region R2, the second side surface S2 may be formed to have a predetermined height. A height h of the second side surface S2 in a second direction D2 may be about 50 μm or more, for example, in a range of about 50 μm to about 1000 μm, about 50 μm to about 500 μm, or about 50 μm to about 300 μm, about 50 μm to about 200 μm, about 50 μm to about 100 μm, or the like, but the inventive concept is not limited thereto. The height h of the second side surface S2 may be determined in consideration of a thickness of an adhesive member (e.g., “120” in FIG. 2B) and a height of each of bumps (e.g., “34” in FIG. 2B).

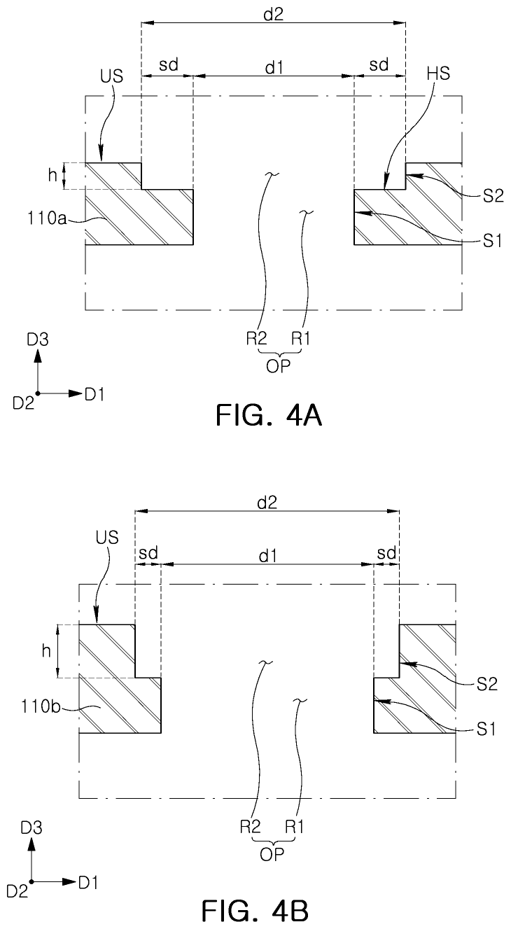

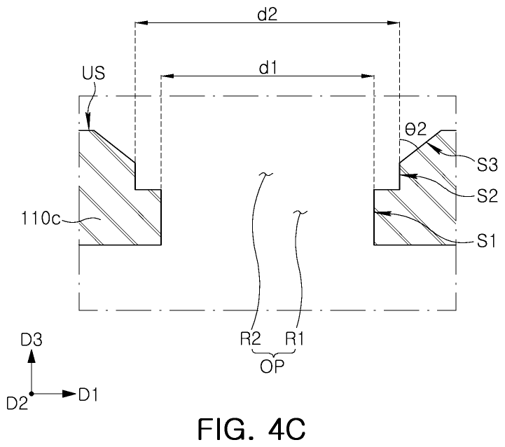

FIGS. 4A to 4C are diagrams illustrating support members 110a, 110b, and 110c according to example embodiments. FIGS. 4A to 4C respectively illustrate some regions of example modifications corresponding to FIG. 3B.

Referring to FIG. 4A, in an example embodiment, a separation distance sd between a first side surface S1 and a second side surface S2 of a support member 110a may be greater than a height h of the second side surface S2. A horizontal surface HS connecting the first side surface S1 and the second side surface S2 to each other may prevent a chip structure from being excessively lowered. In the present embodiment, a width d1 of a lower region R1 may be less than a width of a chip structure (e.g., “30” in FIG. 2B). However, as illustrated in FIG. 2E, an operation of the pickup member 140 according to an example embodiment may be controlled by the control member 150, such that lowering of the pickup member 140 may be stopped without contact with the support member 110.

Referring to FIG. 4B, in an embodiment, a separation distance sd between a first side surface S1 and a second side surface S2 of a support member 110b may be less than a height h of the second side surface S2. The second side surface S2 may formed to have a height to secure a space for lowering of a pickup member and a chip structure.

In some example embodiments, a first side surface S1 and a second side surface S2 may be coplanar with each other, and a width d1 of a lower region R1 may be substantially equal to a width d2 of an upper region R2. That is, as illustrated in FIG. 2E, when an adhesive member 120 has excellent adhesive strength allowing a state of bonding with the chip structures 30 to be maintained in a bent state, the width d1 of the lower region R1 may be equal to or greater than the width d2 of the upper region R2.

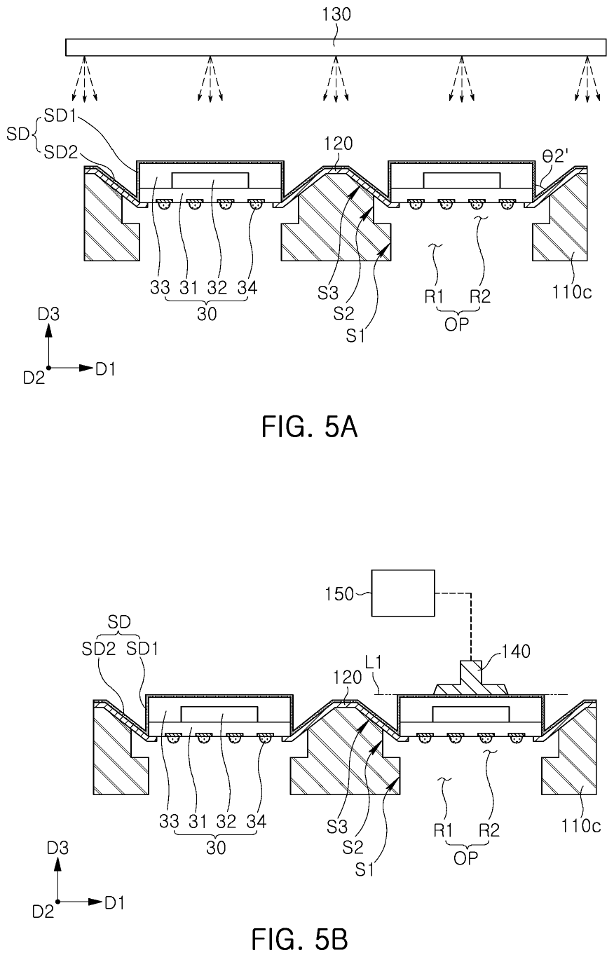

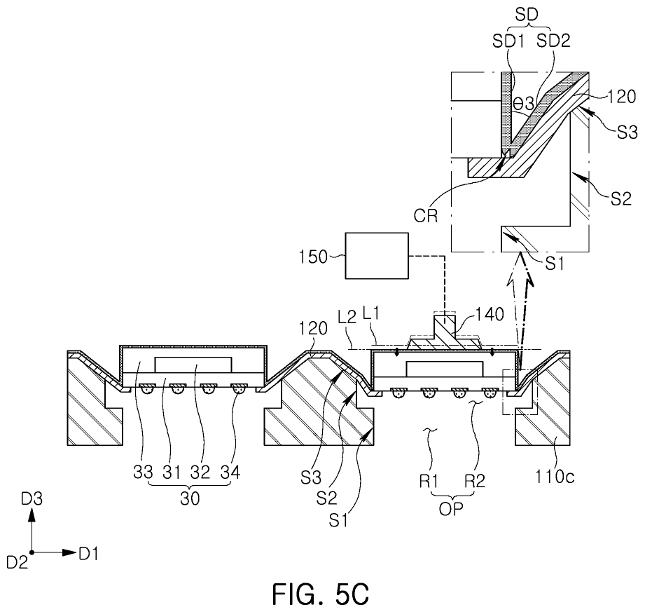

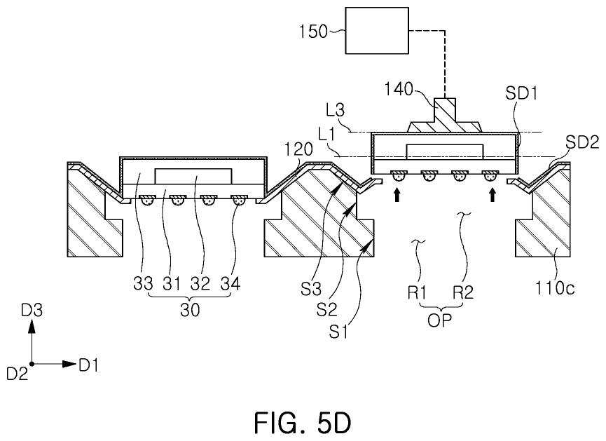

Referring to FIG. 4C, in an example embodiment, a support member 110c may further have a third side surface S3. The third side surface S3 may extend from an end of the second side surface S2. The third side surface S3 may be a portion of a support surface US to which an adhesive member (e.g., “120” in FIG. 5A) is attached. The third side surface S3 may be inclined at an angle with respect to the second side surface S2. The third side surface S3 may be inclined at a second angle θ2 with respect to the second side surface S2. For example, the third side surface S3 may be inclined at the second angle θ2 with respect to a reference line (or reference surface), parallel to the second side surface S2. An acute angle may be formed by the third side surface S3 at a bent portion of a shielding material layer, thereby facilitating cutting of the shielding material layer and preventing the occurrence of a burr.

Hereinafter, an EMI shielding method to which the support member 110c according to an example embodiment is applied will be described with reference to FIGS. 5A to 5C.

FIGS. 5A to 5D are cross-sectional views illustrating an EMI shielding film forming method according to an example embodiment.

Referring to FIG. 5A, a shielding material layer SD covering chip structures 30 and an adhesive member 120 may be formed using a coating member 130. A process of attaching the adhesive member 120 and the chip structure 30 may be similar to that described with reference to FIGS. 2A and 2B, and thus repeated descriptions will be omitted. In addition, the coating member 130 and the shielding material layer SD may have features the same as or similar to those described with reference to FIG. 2C, and thus repeated descriptions will be omitted.

A support member 110c according to an example embodiment may have side surfaces S1 and S2 respectively defining a plurality of openings OP, and an inclined surface (may be referred to as “third side surface S3”) in contact with the adhesive member 120, on or above the side surfaces S1 and S2 in a third direction D3.

The shielding material layer SD may have first portions SD1 respectively covering upper surfaces and side surfaces of the chip structures 30, and second portions SD2 extending from the first portions SD1, the second portions SD2 covering the third side surfaces S3 of the support members 110c. The second portions SD2 may extend along the third side surface S3 of the support member 110c. Accordingly, the first portions SD1 and the second portions SD2 of the shielding material layer SD may have an angle therebetween provided by an inclination of the third side surface S3. An angle θ2′ between the first portions SD1 and the second portions SD2 may be substantially equal to the second angle θ2 between the third side surface S3 and the second side S2 illustrated in FIG. 4C. The angle θ2′ between the first portions SD1 and the second portions SD2 may be an acute angle.

Referring to FIG. 5B, a pickup member 140 may adsorb at least one chip structure 30, among the chip structures 30 covered by the shielding material layer SD, at a first level L1 (S104). The pickup member 140 may adsorb a first portion SD1 of the shielding material layer SD. Thereafter, the pickup member 140 may be lowered to a level, lower than the first level L1, by a control member 150 to move the adsorbed chip structure 30 into an opening OP.

Referring to FIG. 5C, the pickup member 140 may be lowered to a second level L2, which is lower than the first level L1. When the pickup member 140 is lowered to the second level L2, a portion of a corresponding chip structure 30 may be positioned within an upper region R2 of the opening OP.

As the pickup member 140 is lowered, the shielding material layer SD between the first portion SD1 and the second portion SD2 may be bent, and an angle between the first portion SD1 and the second portion SD2 may decrease. For example, at the second level L2, the first portion SD1 and the second portion SD2 may have a third angle θ3, which is less than the angle θ2′ in FIG. 5A, therebetween. The third angle θ3 may be equal to or less than the first angle θ1 in FIG. 2E. Accordingly, a crack CR may occur between the first portion SD1 and the second portion SD2 of the shielding material layer SD to which tensile stress is applied.

Thus, in a case where an acute angle is formed between the first portion SD1 and the second portion SD2 before the pickup member 140 is lowered, a crack CR may easily occur between the first portion SD1 and the second portion SD2 of the shielding material layer SD, even when the pickup member 140 is lowered by a relatively small amount (that is, when L1 and L2 have a slight difference therebetween).

Referring to FIG. 5D, the pickup member 140 may be raised to a third level L3, which is higher than the first level L1. When the pickup member 140 is raised to the third level L3, the first portion SD1 of the shielding material layer SD and the second portion SD2 of the shielding material layer SD may be separated from each other. The first portion SD1 of the shielding material layer SD may function as an EMI shielding film for the chip structure 30. Here, the third level L3 may not indicate a pre-defined value but is used to describe a concept that the pickup member 140 is raised to a level such that the first portion SD1 and the second portion SD2 are entirely separated from each other, and it does not mean that the pickup member 140 is raised only to the third level L3.

Referring to FIGS. 5A to 5D together, an EMI shielding film forming apparatus according to an example embodiment may include a support member 110c having an inclined surface (e.g., the third side surface S3) for forming an acute angle at a bent portion of the shielding material layer SD.

For example, the EMI shielding film forming apparatus according to an example embodiment may include an adhesive member 120 having a pocket region PK in which bumps 34 of a chip structure 30 are accommodated, a support member 110 disposed on or below the adhesive member 120, the support member 110 having an opening OP aligned with the pocket region PK, a coating member 130 configured to form a shielding material layer SD on the adhesive member 120 and the chip structure 30 disposed on the adhesive member 120, and a pickup member 140 configured to detach, from the adhesive member 120, the chip structure 30 covered by the shielding material layer SD.

The support member 110c according to an example embodiment may have a first side surface S1 defining a lower region R1 of the opening OP, a second side surface S2 spaced apart from the first side surface S1 in a first direction D1, the second side surface S2 defining an upper region R2 of the opening OP, and a third side surface S3 in contact with the adhesive member 120, the third side surface S3 inclined at an angle with respect to the second side surface S2. Here, the shielding material layer SD may be bent along a side surface of the chip structure 30 and the third side surface S3 of the support member 110c.

According to example embodiments of the inventive concept, a support member having an opening having a width greater than that of a chip structure may be provided, thereby providing an EMI shielding film forming apparatus having improved yield.

In addition, according to example embodiments of the inventive concept, a support member having an inclined surface along which a shielding material layer is bent may be provided, thereby providing an EMI shielding film forming apparatus having improved yield.

In addition, according to example embodiments of the inventive concept, a shielding material layer may be bent using a pickup member, thereby providing an EMI shielding film forming method having improved yield.

While example embodiments have been shown and described above, it will be apparent to those skilled in the art that modifications and variations may be made without departing from the scope of the inventive concept as defined by the appended claims and their equivalents.

The invention claimed is:

1. An apparatus for forming an electromagnetic interference (EMI) shielding film, the apparatus comprising:
an adhesive member having a pocket region in which bumps of a chip structure are accommodated;
a support member disposed on or below the adhesive member, the support member having an opening at a position aligned with the pocket region;
a coating member configured to form a shielding material layer on the adhesive member and the chip structure disposed on the adhesive member; and
a pickup member configured to detach, from the adhesive member, the chip structure covered by the shielding material layer,
wherein the support member has a first side surface defining a lower region of the opening, and a second side surface spaced apart from the first side surface in a first direction, the second side surface defining an upper region of the opening, and
a first width of the lower region in the first direction is less than a second width of the upper region in the first direction.

2. The apparatus of claim 1, wherein the second width of the upper region is greater than a third width of the chip structure in the first direction.

3. The apparatus of claim 2, wherein a width of the pocket region in the first direction is less than the third width of the chip structure.

4. The apparatus of claim 1, wherein a height of the second side surface in a second direction, perpendicular to the first direction, is about 50 μm or more.

5. The apparatus of claim 1, wherein a separation distance between the first side surface and the second side surface is about 50 μm or more.

6. The apparatus of claim 1, wherein
the shielding material layer has a first portion on an upper surface and a side surface of the chip structure, and a second portion on an upper surface of the adhesive member exposed from the chip structure, and
the apparatus further includes a control member configured to control the pickup member to separate the first portion and the second portion from each other for detachment of the chip structure.

7. The apparatus of claim 6, wherein
the control member is configured to sequentially move the pickup member to a first level to adsorb the first portion, to a second level, which is lower than the first level, and to a third level, which is higher than the first level.

8. The apparatus of claim 1, wherein
the support member further has a third side surface extending from the second side surface, and
the third side surface is inclined at a first angle with respect to the second side surface.

9. The apparatus of claim 8, wherein the shielding material layer has a first portion on an upper surface and a side surface of the chip structure, and a second portion on the adhesive member covering the third side surface.

10. The apparatus of claim 9, wherein an angle between the first portion and the second portion is substantially equal to the first angle.

11. The apparatus of claim 9, wherein
the pickup member is sequentially moved to a first level to adsorb the first portion, to a second level, which is lower than the first level, and to a third level, which is higher than the first level.

12. The apparatus of claim 1, wherein the shielding material layer includes at least one-layer conductive film extending along an upper surface of the chip structure, a side surface of the chip structure, and an upper surface of the adhesive member exposed from the chip structure.

13. The apparatus of claim 12, wherein the at least one-layer conductive film includes any one of iron (Fe), nickel (Ni), gold (Au), silver (Ag), copper (Cu), or an alloy thereof.

14. An apparatus for forming an electromagnetic interference (EMI) shielding film, the apparatus comprising:
an adhesive member having a pocket region in which bumps of a chip structure are accommodated;
a support member disposed on or below the adhesive member, the support member having an opening at a position aligned with the pocket region;
a coating member configured to form a shielding material layer on the adhesive member and the chip structure disposed on the adhesive member; and
a pickup member configured to detach, from the adhesive member, the chip structure covered by the shielding material layer,
wherein the support member has a first side surface defining a lower region of the opening, a second side surface defining an upper region of the opening, and a third side surface in contact with the adhesive member, the third side surface being inclined at an angle with respect to the second side surface.

15. The apparatus of claim 14, wherein the shielding material layer is bent along a side surface of the chip structure and the third side surface of the support member.

16.-20. (canceled)
